(19) United States
(12) Patent Application Publication
(10) Pub. No.: US 2024/0081143 A1
(43) Pub. Date: Mar. 7, 2024

(54) METHOD OF PREPARING PEROVSKITE THROUGH ANTI-SOLVENT EVAPORATION-CONTROLLED METHOD AND PEROVSKITE PREPARED USING SAME

(71) Applicant: EWHA UNIVERSITY-INDUSTRY COLLABORATION FOUNDATION, Seoul (KR)

(72) Inventors: Dong Ha KIM, Seoul (KR); Yoonseo NAH, Incheon (KR)

(21) Appl. No.: 18/507,186

(22) Filed: Nov. 13, 2023

Related U.S. Application Data
(63) Continuation of application No. PCT/KR2021/012600, filed on Sep. 15, 2021.

(30) Foreign Application Priority Data
May 14, 2021 (KR) 10-2021-0062824

(51) Int. Cl. H10K 85/50; C07F 7/24; C09K 11/06

(52) U.S. Cl. CPC H10K 85/50; C07F 7/24; C09K 11/06; H10K 50/11

(57) ABSTRACT

The present disclosure relates to a method of preparing perovskite using an anti-solvent evaporation-controlled method and perovskite prepared thereby.

### CROSS-REFERENCE TO RELATED APPLICATIONS

This application is a continuation of PCT Application No. PCT/KR2021/012600, filed on Sep. 15, 2021, which claims priority to Korean Patent Applications No. 10-2021-0062824 filed on May 14, 2021, both of which are hereby incorporated by reference in their entirety.

### TECHNICAL FIELD

The present disclosure relates to a method of preparing perovskite using an anti-solvent evaporation-controlled method and perovskite prepared thereby.

### BACKGROUND

An organic-inorganic metal halide perovskite material absorbs light in a wide wavelength band including a visible light range and has high carrier mobility and low trap density. Thus, it has received a lot of attention as a material of electronic devices including high-efficiency solar cells. For example, methylammonium (MA, CH₃NH₃) lead iodide (MAPbI₃) perovskite has the advantage of serving as an absorber layer of a high-efficiency solar cell with appropriate band gap energy, high absorption coefficient, and long-distance bipolar photocarrier diffusion. Also, the organic-inorganic metal halide perovskite is crystallized by self-assembly and thus can be prepared by a low-cost solution process. However, when the organic-inorganic metal halide perovskite is prepared by the solution process, the crystallization rate is very high. Therefore, it is difficult to form a uniform film, and the formed phase is widely distributed.

Meanwhile, applying an anti-solvent that does not dissolve perovskite in a solution process but selectively dissolves a solvent of a precursor solution has been known as a method for forming a uniform perovskite film. However, it has been known that the anti-solvent process accelerates the crystallization of perovskite in a localized area, and thus, a finally synthesized perovskite material has a wide phase distribution.

### PRIOR ART DOCUMENT

### Non-Patent Literature

Korean Patent Laid-open Publication No. 10-2018-0096044

### DISCLOSURE OF THE INVENTION

### Problems to be Solved by the Invention

The present disclosure relates to a method of preparing perovskite using an anti-solvent evaporation-controlled method and perovskite prepared thereby.

However, problems to be solved by the present disclosure are not limited to the above-described problems, and although not described herein, other problems to be solved by the present disclosure can be clearly understood by those skilled in the art from the following descriptions.

### Means for Solving the Problems

A first aspect of the present disclosure provides a method of preparing perovskite using an anti-solvent evaporation-controlled method, including: a precursor solution applying process of applying a perovskite precursor solution onto a substrate; and an anti-solvent applying process of applying an anti-solvent onto the applied perovskite precursor solution, in the precursor solution applying process, temperatures of the substrate and the perovskite precursor solution are in the range of ±20° C. of the boiling point of the anti-solvent.

A second aspect of the present disclosure provides a perovskite prepared by the method according to the first aspect.

A third aspect of the present disclosure provides a light emitting diode including perovskite according to the second aspect as an emission layer.

### Effects of the Invention

In a method of preparing perovskite using an anti-solvent evaporation-controlled method according to embodiments of the present disclosure, temperatures of a substrate and a perovskite precursor solution are set to the range of ±20° C. of the boiling point of the anti-solvent. Thus, the evaporation rate of the anti-solvent on the applied perovskite precursor solution can be uniformly controlled and the crystallization rate can be uniformly controlled over the entire range on the applied perovskite precursor solution.

Perovskite prepared using an anti-solvent evaporation-controlled method according to embodiments of the present disclosure has a quasi-two dimensional profile by controlling temperatures of a substrate and a perovskite precursor solution to be in the range of ±20° C. of the boiling point of the anti-solvent. Thus, the perovskite has a quasi-two dimensional profile with a narrow phase distribution and has a smooth surface morphology.

Due to the anti-solvent evaporation, the perovskite prepared by the anti-solvent evaporation-controlled method according to embodiments of the present disclosure can have a quasi-two dimensional profile with a narrow phase distribution regardless of the kind of material.

Due to the quasi-two dimensional profile with a narrow phase distribution, the perovskite prepared by the anti-solvent evaporation-controlled method according to embodiments of the present disclosure can emit clear blue light with high efficiency when applied to a light emitting diode.

### BRIEF DESCRIPTION OF THE DRAWINGS

FIGS. 1A to 1C are schematic diagrams showing processes of forming perovskite using an anti-solvent evaporation-controlled method, in an example of the present disclosure.

FIG. 2 shows structures of perovskite-based light emitting diodes (LEDs) fabricated by an anti-solvent evaporation-controlled method, a hot-casting method, and an anti-solvent method, in an example of the present disclosure.

FIGS. 3A and 3B show an absorption spectrum (FIG. 3A) and an emission spectrum (FIG. 3B) depending on temperatures of a precursor solution and a substrate of perovskite (PEA₂CsPb₂Br₇) prepared by an anti-solvent evaporation-controlled method, respectively, in an example of the present disclosure.

FIGS. 4A to 4C show absorption and emission spectra of perovskite (PEA₂CsPb₂Br₇) prepared by an anti-solvent evaporation-controlled method (FIG. 4A), a hot-casting method (FIG. 4B), and an anti-solvent method (FIG. 4C), respectively, in an example of the present disclosure.

FIGS. 5A and 5B show absorption (FIG. 5A) and emission (FIG. 5B) spectra of perovskite (BA₂CsPb₂Br₇) prepared by an anti-solvent evaporation-controlled method, a hot-casting method, and an anti-solvent method, respectively, in an example of the present disclosure. FIGS. 5C and 5D show absorption (FIG. 5C) and emission (FIG. 5D) spectra of perovskite(nHA₂CsPb₂Br₇) prepared by an anti-solvent evaporation-controlled method, a hot-casting method, and an anti-solvent method, respectively, in an example of the present disclosure. FIGS. 5E and 5F show absorption (FIG. 5E) and emission (FIG. 5F) spectra of perovskite (PEACsPb₂I₇) prepared by an anti-solvent evaporation-controlled method, a hot-casting method, and an anti-solvent method, respectively, in an example of the present disclosure. FIGS. 5G and 5H show absorption (FIG. 5G) and emission (FIG. 5H) spectra of perovskite (iPA₂CsPb₂Br₇) prepared by an anti-solvent evaporation-controlled method, a hot-casting method, and an anti-solvent method, respectively, in an example of the present disclosure.

FIGS. 6A to 6C show X-ray diffraction (XRD) graphs of perovskite (PEA₂CsPb₂Br₇) prepared by a hot-casting method (FIG. 6A), an anti-solvent method (FIG. 6B), and an anti-solvent evaporation-controlled method (FIG. 6C), respectively, in an example of the present disclosure.

FIGS. 7A to 7F show atomic force microscopy (AFM) images of perovskite (PEA₂CsPb₂Br₇) prepared by a hot-casting method (FIGS. 7A and 7B), an anti-solvent method (FIGS. 7C and 7D), and an anti-solvent evaporation-controlled method (FIGS. 7E and 7F), respectively, in an example of the present disclosure.

FIGS. 8A to 8C and FIGS. 8D(i) to 8D(iii) show a current density graph (FIG. 8A), an external quantum efficiency graph (FIG. 8B), and electroluminescence spectra (FIG. 8C and FIGS. 8D(i) to 8D(iii)) of perovskite(PEA₂CsPb₂Br₇)-based LEDs fabricated by an anti-solvent evaporation-controlled method, a hot-casting method, and an anti-solvent method, respectively, in an example of the present disclosure.

FIGS. 9A to 9C show an electroluminescence spectrum (FIG. 9A), an external quantum efficiency graph (FIG. 9B), and a current density graph (FIG. 9C) of perovskite (BA₂CsPb₂Br₇)-based LEDs fabricated by an anti-solvent evaporation-controlled method, a hot-casting method, and an anti-solvent method, respectively, in an example of the present disclosure.

FIGS. 10A to 10C show an electroluminescence spectrum (FIG. 10A), an external quantum efficiency graph (FIG. 10B), and a current density graph (FIG. 10C) of perovskite (nHA₂CsPb₂Br₇)-based LEDs fabricated by an anti-solvent evaporation-controlled method, a hot-casting method, and an anti-solvent method, respectively, in an example of the present disclosure.

FIGS. 11A to 11C show an electroluminescence spectrum (FIG. 11A), an external quantum efficiency graph (FIG. 11B), and a current density graph (FIG. 11C) of perovskite (iPA₂CsPb₂Br₇)-based LEDs fabricated by an anti-solvent evaporation-controlled method, a hot-casting method, and an anti-solvent method, respectively, in an example of the present disclosure.

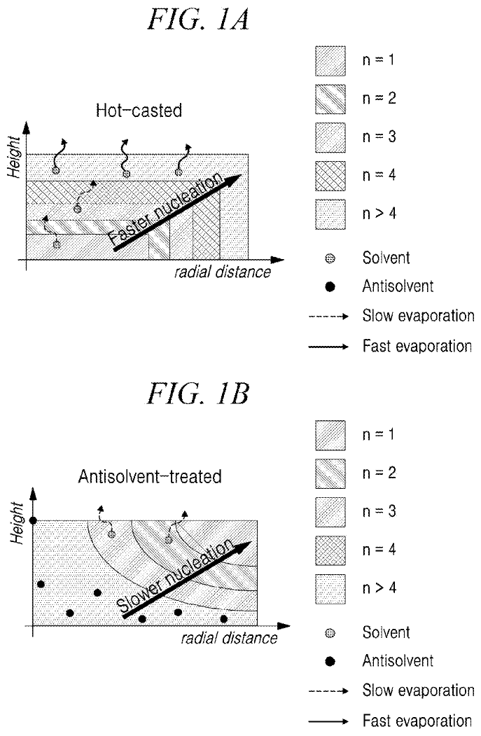

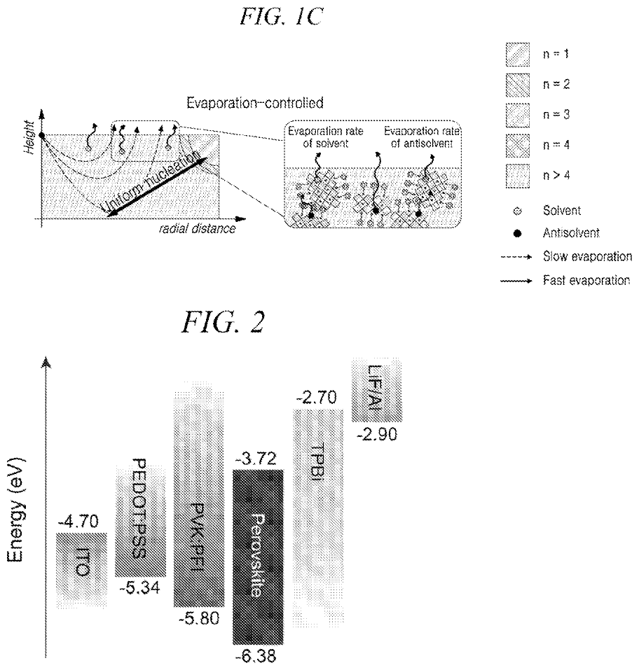

### BEST MODE FOR CARRYING OUT THE INVENTION

Hereinafter, embodiments and examples of the present disclosure will be described in detail with reference to the accompanying drawings so that the present disclosure may be readily implemented by those skilled in the art. However, it is to be noted that the present disclosure is not limited to the embodiments and examples but can be embodied in various other ways. In drawings, parts irrelevant to the description are omitted for the simplicity of explanation, and like reference numerals denote like parts through the whole document.

Through the whole document, the term “connected to” or “coupled to” that is used to designate a connection or coupling of one element to another element includes both a case that an element is “directly connected or coupled to” another element and a case that an element is “electronically connected or coupled to” another element via still another element.

Through the whole document, the term “on” that is used to designate a position of one element with respect to another element includes both a case that the one element is adjacent to the other element and a case that any other element exists between these two elements.

Further, through the whole document, the term “comprises or includes” and/or “comprising or including” used in the document means that one or more other components, steps, operation and/or existence or addition of elements are not excluded in addition to the described components, steps, operation and/or elements unless context dictates otherwise.

Through the whole document, the term “about or approximately” or “substantially” is intended to have meanings close to numerical values or ranges specified with an allowable error and intended to prevent accurate or absolute numerical values disclosed for understanding of the present disclosure from being illegally or unfairly used by any unconscionable third party.

Through the whole document, the term “step of” does not mean “step for”.

Through the whole document, the term “combination(s) of” included in Markush type description means mixture or combination of one or more components, steps, operations and/or elements selected from a group consisting of components, steps, operation and/or elements described in Markush type and thereby means that the disclosure includes one or more components, steps, operations and/or elements selected from the Markush group.

Through the whole document, a phrase in the form “A and/or B” means “A or B, or A and B”.

Through the whole document, the term “alkyl” or “alkyl group” may individually include linear or branched alkyl groups having 1 to 12 carbon atoms, 1 to 10 carbon atoms, 1 to 8 carbon atoms, or 1 to 5 carbon atoms, and all the possible isomers thereof. For example, the alkyl or alkyl group may individually include methyl group (Me), ethyl group (Et), n-propyl group (ⁿPr), iso-propyl group (ⁱPr), n-butyl group (ⁿBu), iso-butyl group (ⁱBu), tert-butyl group (^{t}Bu), sec-butyl group (^{s}Bu), n-pentyl group (ⁿPe), iso-pentyl group (ⁱPe), sec-pentyl group (^{s}Pe), tert-pentyl group (^{t}Pe), n-hexyl group, iso-hexyl group, heptyl group, 4,4-dimethyl pentyl group, octyl group, 2,2,4-trimethyl pentyl group, nonyl group, decyl group, undecyl group, dodecyl group, and isomers thereof, but may not be limited thereto.

In the following description, exemplary embodiments of the present disclosure will be described in detail, but the present disclosure may not be limited thereto.

A first aspect of the present disclosure provides a method of preparing perovskite using an anti-solvent evaporation-controlled method, including: a precursor solution applying process of applying a perovskite precursor solution onto a substrate; and an anti-solvent applying process of applying an anti-solvent onto the applied perovskite precursor solution, in the precursor solution applying process, temperatures of the substrate and the perovskite precursor solution are in the range of ±20° C. of the boiling point of the anti-solvent.

In an embodiment of the present disclosure, the anti-solvent may include at least one selected from toluene, chlorobenzene and chloroform, but may not be limited thereto.

In an embodiment of the present disclosure, the anti-solvent is brought into contact with the precursor solution, and, thus, the solubility of the precursor solution decreases, which serves to accelerate the crystallization of perovskite.

In an embodiment of the present disclosure, an evaporation rate of the anti-solvent on the applied perovskite precursor solution can be uniformly controlled by setting the temperatures of the substrate and the perovskite precursor solution to the range of ±20° C. of the boiling point of the antisolvent. Specifically, the temperatures of the substrate and the perovskite precursor solution may be in the range of about ±20° C., about ±18° C., about ±16° C., about ±14° C., about ±12° C., about ±10° C., about ±9° C., about ±8° C., about ±7° C., about ±6° C., about ±5° C., about ±4° C., about ±3° C., about ±2° C., about ±1° C., or about ±0.5° C. of the boiling point of the anti-solvent. For example, if the anti-solvent is toluene, the temperatures of the substrate and the perovskite precursor solution may be in the range of about 90° C. to about 130° C., about 92° C. to about 128° C., about 94° C. to about 126° C., about 96° C. to about 124° C., about 98° C. to about 122° C., about 100° C. to about 120° C., about 101° C. to about 119° C., about 102° C. to about 118° C., about 103° C. to about 117° C., about 104° C. to about 116° C., about 105° C. to about 115° C., about 106° C. to about 114° C., about 107° C. to about 113° C., about 108° C. to about 112° C., about 109° C. to about 111° C., or about 109.5° C. to about 110.5° C.

In an embodiment of the present disclosure, the evaporation rate of the anti-solvent applied on the perovskite precursor solution is uniformly controlled. Thus, the crystallization rate can be uniformly controlled over the entire range on the applied perovskite precursor solution. The crystallization rate on a surface of the applied perovskite precursor solution may match the crystallization rate on the interface between the applied perovskite and the substrate.

In an embodiment of the present disclosure, the precursor solution applying process may be performed by at least one selected from a spin-coating method, a spray-coating method, and a dip-coating method, but may not be limited thereto.

In an embodiment of the present disclosure, the anti-solvent applying process may be performed by at least one selected from a spin-coating method, a spray-coating method, and a dip-coating method, but may not be limited thereto. For example, if the precursor solution applying process and the anti-solvent applying process are performed by spin-coating, the precursor solution is applied onto the substrate, followed by spin-coating. Before spin-coating is completed, the anti-solvent is applied onto the precursor solution. Thus, a series of processes of spin-coating are completed.

In an embodiment of the present disclosure, the method may further include an annealing process after the anti-solvent applying process.

In an embodiment of the present disclosure, quasi-two dimensional perovskite crystals in which the number of unit cell (n) is an integer of 1 to 3 may be obtained with a ratio of about 95% or more of all crystals by the method of preparing perovskite. Specifically, quasi-two dimensional perovskite crystals in which the number of unit cell (n) is an integer of 1 to 3 may be obtained with a ratio of about 95% or more, about 96% or more, about 97% or more, about 98% or more, or about 99% or more of all crystals by the method of preparing perovskite. A conventional technique of simply applying an anti-solvent onto a perovskite precursor solution accelerates the crystallization of perovskite in a localized area on the precursor solution. Thus, a finally synthesized perovskite material has a wide phase distribution. However, according to the present disclosure, the evaporation rate of the anti-solvent applied on the precursor solution is uniformly controlled by the method of preparing perovskite using the anti-solvent evaporation-controlled method. Thus, the crystallization rate can be uniformly controlled over the entire range on the coated perovskite precursor solution. Therefore, quasi-two dimensional perovskite crystals in which the number of unit cell (n) is an integer of 1 to 3 can be obtained with a ratio of about 95% or more, about 96% or more, about 97% or more, about 98% or more, or about 99% or more of all crystals.

A second aspect of the present disclosure provides a perovskite prepared by the method according to the first aspect.

In an embodiment of the present disclosure, the perovskite may be represented by the following Chemical Formula 1:

(ANH₃)₂B₍ₘ₋₁₎CₘX₃ₘ₊₁ [Chemical Formula 1]

In the Chemical Formula 1, A includes an arylalkyl group or a linear alkyl group having 1 to 10 carbon atoms, B includes at least one selected from RNH₃ and Cs, R includes a linear or branched alkyl group having 1 to 10 carbon atoms, C includes at least one metal cation selected from Pb²⁺, Cu²⁺, Ni²⁺, Co²⁺, Fe²⁺, Mn²⁺, Cr²⁺, Pd²⁺, Cd²⁺, Yb²⁺, Sn²⁺ and Ge²⁺, X includes at least one halide anion selected from Cl⁻, Br⁻ and I⁻, and m is an integer of 2 or more.

In an embodiment of the present disclosure, the perovskite may be represented by the following Chemical Formula 2:

(ANH₃)₂B₍ₘ₋₁₎PbₘX₃ₘ₊₁ [Chemical Formula 2]

In the Chemical Formula 2, A includes an arylalkyl group or a linear alkyl group having 1 to 10 carbon atoms, B includes at least one selected from RNH₃ and Cs, R includes a linear or branched alkyl group having 1 to 10 carbon atoms, X includes at least one halide anion selected from Cl⁻, Br⁻ and I⁻, and m is an integer of 2 or more.

In an embodiment of the present disclosure, the perovskite may include at least one selected from PEA₂CsPb₂Br₇ (PEA: phenethyl ammonium), BA₂CsPb₂Br₇ (BA: benzyl ammonium), nHA₂CsPb₂Br₇ (nHA: n-hexyl ammonium), PEA₂CsPb₂I₇, PEA₂MAPb₂Br₇ (MA: methyl ammonium), and iPA₂CsPb₂Br₇ (iPA: isopropyl ammonium), but may not be limited thereto.

In an embodiment of the present disclosure, the perovskite may be crystallized at a uniform rate over the entire range on the perovskite precursor solution. Thus, the perovskite may have a smooth surface morphology and may have a quasi-two dimensional profile with a narrow phase distribution.

In an embodiment of the present disclosure, the perovskite may have a quasi-two dimensional profile in which the number of unit cell (n) is an integer of 1 to 3.

In an embodiment of the present disclosure, the perovskite may have a maximum photoluminescence peak at a wavelength range of about 440 nm to about 500 nm. Specifically, the perovskite may have a maximum photoluminescence peak at a wavelength range of about 440 nm to about 500 nm, about 445 nm to about 500 nm, about 450 nm to about 500 nm, about 455 nm to about 500 nm, about 460 nm to about 500 nm, about 465 nm to about 500 nm, about 440 nm to about 490 nm, about 445 nm to about 490 nm, about 450 nm to about 490 nm, about 455 nm to about 490 nm, about 460 nm to about 490 nm, about 465 nm to about 490 nm, about 440 nm to about 480 nm, about 445 nm to about 480 nm, about 450 nm to about 480 nm, about 455 nm to about 480 nm, about 460 nm to about 480 nm, about 465 nm to about 480 nm, about 440 nm to about 475 nm, about 445 nm to about 475 nm, about 450 nm to about 475 nm, about 455 nm to about 475 nm, about 460 nm to about 475 nm, about 465 nm to about 475 nm, about 440 nm to about 470 nm, about 445 nm to about 470 nm, about 450 nm to about 470 nm, about 455 nm to about 470 nm, about 460 nm to about 470 nm, about 465 nm to about 470 nm, about 440 nm to about 467 nm, about 445 nm to about 467 nm, about 450 nm to about 467 nm, about 455 nm to about 467 nm, about 460 nm to about 467 nm, or about 465 nm to about 467 nm.

In an embodiment of the present disclosure, the perovskite may have a full width at half maximum of the maximum photoluminescence peak of about 20 nm or less. Specifically, the perovskite may have a full width at half maximum of the maximum photoluminescence peak of about 20 nm or less, about 19 nm or less, about 18 nm or less, about 17 nm or less, about 16 nm or less, about 15 nm or less, or about 14 nm or less.

A third aspect of the present disclosure provides a light emitting diode including perovskite according to the second aspect as an emission layer.

In an embodiment of the present disclosure, the light emitting diode may include a substrate, a first electrode layer formed on the substrate, a hole injection layer formed on the first electrode layer, an emission layer including the perovskite and formed on the hole injection layer, an electron transport layer formed on the emission layer, and a second electrode layer formed on the electron transport layer, but may not be limited thereto.

In an embodiment of the present disclosure, the light emitting diode may include, for example, an indium tin oxide (ITO) substrate, a poly(3,4-ethylenedioxythiophene) polystyrene sulfonate (PEDOT:PSS) layer formed on the ITO substrate, a poly(9-vinylcarbazole) (PVK) layer formed on the PEDOT:PSS layer, a perovskite layer formed on the PVK layer, a polymethyl methacrylate (PMMA) layer formed on the perovskite layer, a 2,2′,2″-(1,3,5-Benzinetriyl)-tris(1-phenyl-1-H-benzimidazole (TPBi) layer formed on the PMMA layer, and an LiF/Al layer formed on the TPBi layer, but may not be limited thereto.

In an embodiment of the present disclosure, the light emitting diode may exhibit stable emission characteristics due to the perovskite layer prepared by the anti-solvent evaporation-controlled method. Specifically, the stable emission characteristics of the light emitting diode may be manifested by the appearance of a peak of an electroluminescence spectrum (EL spectrum) in a predetermined wavelength band.

Detailed descriptions on the second aspect and the third aspect of the present disclosure, which overlap with those on the first aspect of the present disclosure, are omitted hereinafter, but the descriptions of the first aspect of the present disclosure may be identically applied to the second aspect and the third aspect of the present disclosure, even though they are omitted hereinafter.

Hereinafter, example embodiments are described in more detail by using Examples, but the present disclosure may not limited to the Examples.

### MODE FOR CARRYING OUT THE INVENTION

### EXAMPLE 1

### Fabrication of Perovskite Thin Film and Light Emitting Diode (LED) Using Anti-Solvent Evaporation-Controlled Method

1) Preparation of Perovskite (PE₂CsPb₂Br₂) precursor solution

A perovskite precursor solution was prepared by dissolving stoichiometric amounts of lead(II) bromide (PbBr₂), 2-phenylethylammonium bromide (PEABr), and cesium bromide (CsBr) in a solvent, dimethyl sulfoxide (DMSO). A molar concentration of PbBr₂ in the perovskite precursor solution was 0.03 M. To improve the crystallinity of a perovskite thin film, 20 mg/mL of n-propylammonium bromide (nPABr) was added to the precursor solution. The precursor solution was vigorously stirred at 110° C. for 20 minutes and then filtered through a polytetrafluoroethylene syringe filter (0.2 μm).

2) Fabrication of Perovskite Thin Film Using Anti-Solvent Evaporation-Controlled Method

The perovskite precursor solution was heated to 110° C. and then dropped onto a substrate heated to 110° C., immediately followed by spin-coating (4000 rpm, 20 seconds). An anti-solvent, toluene, (150 μL) was dropped during spin-coating. After spin-coating was completed, the thin film was annealed (100° C., 4 minutes). Further, to investigate the effect of temperatures of the precursor solution and the substrate on the evaporation rate of the anti-solvent, the temperatures of the precursor solution and the substrate were set to 20° C., 65° C., and 155° C. and an additional perovskite thin film was fabricated.

3) Fabrication of LED

PEDOT:PSS (poly(3,4-ethylenedioxythiophene) polystyrene sulfonate) was spin-coated (5000 rpm, 40 seconds) onto a previously cleaned ITO (indium tin oxide) substrate and then annealed (150° C., 20 minutes). Poly(9-vinylcarbazole) (PVK) (3 mg/mL) dissolved in chlorobenzene was spin-coated (4000 rpm, 35 seconds) on the PEDOT:PSS layer and then annealed (100° C., 20 minutes). Thereafter, to reduce a barrier to hole injection, perfluorinated resin solution (PFI) (0.1 wt %) mixed with isopropyl alcohol was spin-coated (4000 rpm, 30 seconds) and a PVK:PFI layer was formed. Then, a perovskite thin film was formed using an anti-solvent evaporation-controlled method. A BCP (bathocuproine) layer (10 nm), a TPBi (2,2′,2″-(1,3,5-Benzinetriyl)-tris(1-phenyl-1-H-benzimidazole)) layer (40 nm), an LiF layer (2 nm), and an Al layer (70 nm) were sequentially deposited on the perovskite layer by thermal evaporation (pressure<1.0×10⁻⁶ torr) (FIG. 2). The deposition rates of the organic layer and the metal layer were 0.1 nm/s and 0.3 nm/s, respectively.

### EXAMPLE 2

### Fabrication of Perovskite Thin Film of Various Materials Using Anti-Solvent Evaporation-Controlled Method

A perovskite thin film was fabricated using the anti-solvent evaporation-controlled method in the same manner as in Example 1. Perovskite thin films were formed of perovskite materials, BA₂CsPb₂Br₇, nHA₂CsPb₂Br₇, PEA₂CsPb₂I₇, and iPA₂CsPb₂Br₇. Also, light emitting diodes including BA₂CsPb₂Br₇, nHA₂CsPb₂Br₇, PEA₂CsPb₂I₇, and iPA₂CsPb₂Br₇ perovskite thin films as perovskite thin films, respectively, were fabricated in the same manner as in Example 1.

### COMPARATIVE EXAMPLE 1

### Fabrication of Perovskite Thin Film and LED by Hot-Casting Method

1) Fabrication of Perovskite Thin Film Using Hot-Casting Method

Each of perovskite (PEA₂CsPb₂Br₇, BA₂CsPb₂Br₇, nHA₂CsPb₂Br₇, and iPA₂CsPb₂Br₇) precursor solutions used in Example 1 and Example 2 was heated and then dropped onto a substrate heated to 110° C., immediately followed by spin-coating (4000 rpm, 20 seconds) to fabricate a perovskite thin film using a hot casting method.

2) Fabrication of LED

The perovskite thin film fabricated using the hot casting method was fabricated into an LED in the same manner as in Example 1.

### COMPARATIVE EXAMPLE 2

### Fabrication of Perovskite Thin Film and LED Using Anti-Solvent Method

1) Fabrication of perovskite thin film using anti-solvent method

Each of perovskite (PEA₂CsPb₂Br₇, BA₂CsPb₂Br₇, nHA₂CsPb₂Br₇, and iPA₂CsPb₂Br₇) precursor solutions used in Example 1 and Example 2 was cooled to room temperature and then spin-coated (4000 rpm, 20 seconds). An anti-solvent, toluene, (150 μL) was dropped during spin-coating to fabricate a perovskite thin film using an anti-solvent method.

2) Fabrication of LED

The perovskite thin film fabricated using the anti-solvent method was fabricated into an LED in the same manner as in Example 1.

### TEST EXAMPLE 1

### Measurement of Absorption and Emission Characteristics

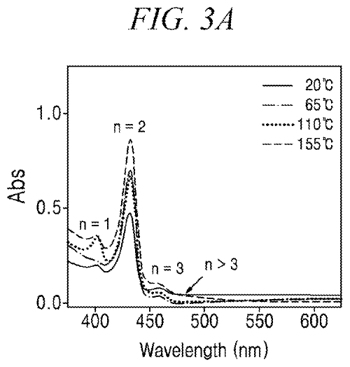

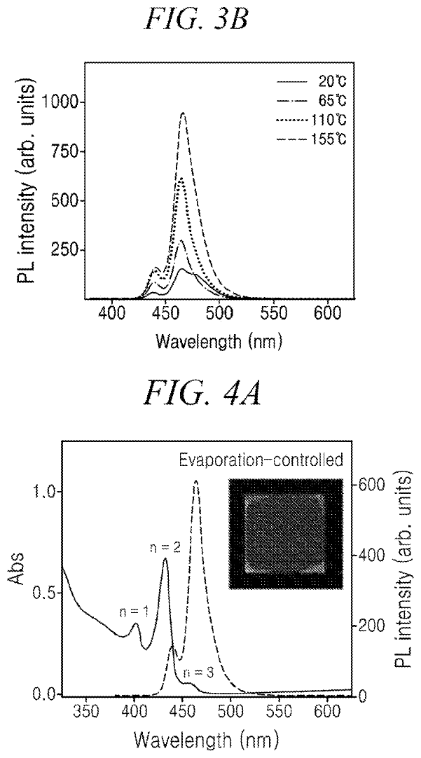

1) By using the perovskite (PEA₂CsPb₂Br₇) precursor solution of Example 1, absorption and emission spectra of perovskite thin films fabricated at different temperatures of the solution and the substrate were measured (FIGS. 3A and 3B). According to the measurement result, it was confirmed that when a perovskite thin film was fabricated using the anti-solvent evaporation-controlled method, perovskite exhibited a wider phase distribution as the difference between the boiling point of the anti-solvent (toluene, boiling point of 110° C.) and the temperatures of the precursor solution and the substrate increased.

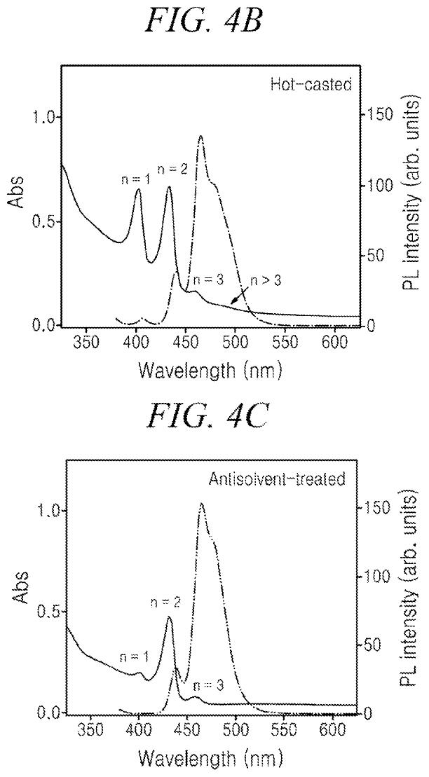

2) According to the measurement result of absorption and emission spectra of perovskite thin films (PEA₂CsPb₂Br₇) fabricated in Example 1 (anti-solvent evaporation-controlled method), Comparative Example 1 (hot-casting method) and Comparative Example 2 (anti-solvent method), it was confirmed that perovskite synthesized by the anti-solvent evaporation-controlled method exhibited the narrowest phase distribution (FIGS. 4A to 4C). FIG. 4B shows absorption and emission spectra of perovskite synthesized by the hot-casting method. According to the absorption spectra, it was confirmed that a wide phase distribution appeared from single-layered (n=1) perovskite to quasi-three dimensional (n>3) perovskite, and several peaks appeared in the emission spectrum due to the wide phase distribution. FIG. 4C shows absorption and emission spectra of perovskite synthesized by the anti-solvent method, and confirms that the quasi-three dimensional (n>3) perovskite caused an increase in width of the emission spectrum. Meanwhile, FIG. 4A shows absorption and emission spectra of perovskite synthesized by the anti-solvent evaporation-controlled method, and confirms that no peak corresponding to the quasi-three dimensional (n>3) perovskite appeared and perovskite with n=3 finally emitted light (dark blue) and exhibited the narrowest phase distribution.

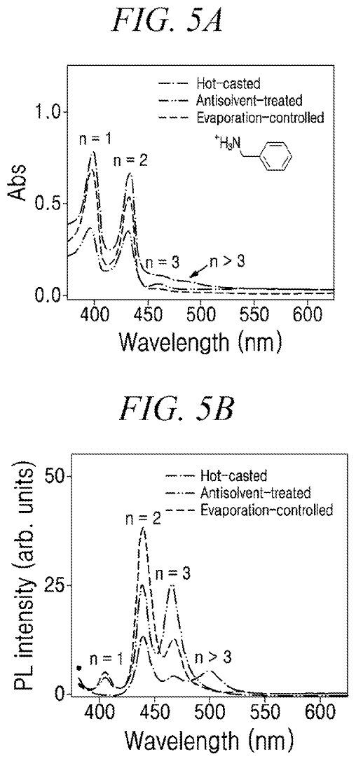

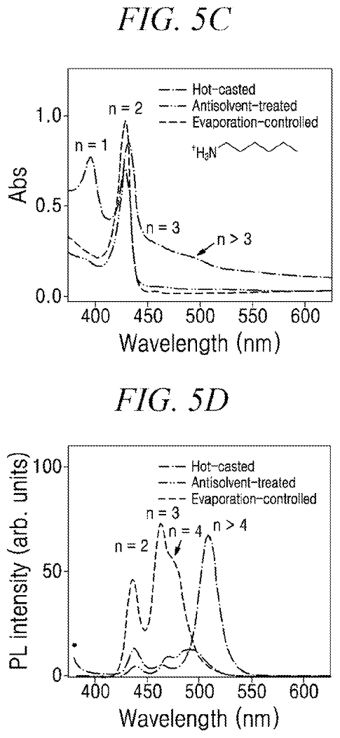

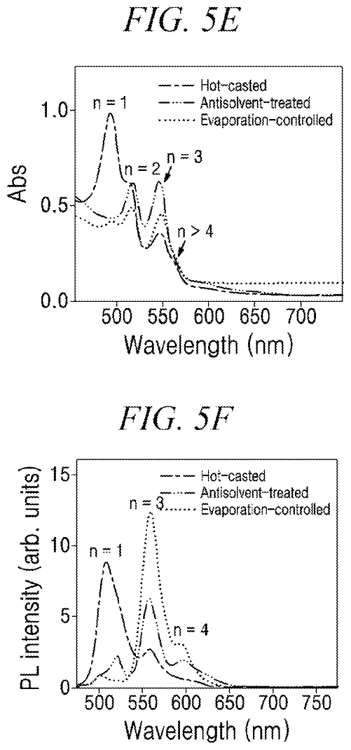

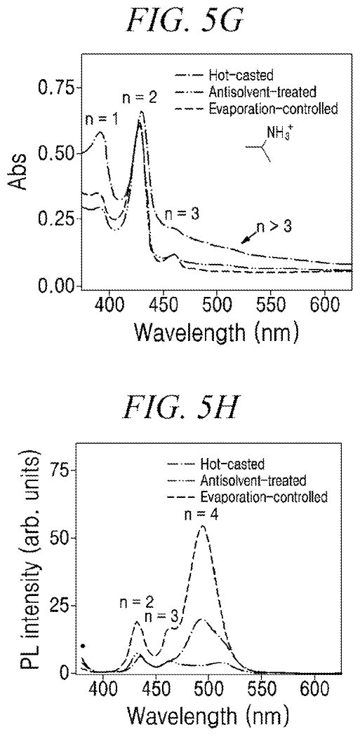

3) Absorption and emission spectra of perovskite (BA₂CsPb₂Br₇, nHA₂CsPb₂Br₇, PEACsPb₂I₇, and iPA₂CsPb₂Br₇) thin films fabricated in Example 1 (anti-solvent evaporation-controlled method), Comparative Example 1 (hot-casting method) and Comparative Example 2 (anti-solvent method) were measured (FIGS. 5A to 5H). It was confirmed that all of the perovskite thin films BA₂CsPb₂Br₇, nHA₂CsPb₂Br₇, PEACsPb₂I₇, and iPA₂CsPb₂Br₇ exhibited the narrowest phase distribution when synthesized using the anti-solvent evaporation-controlled method.

### TEST EXAMPLE 2

### X-Ray Diffraction (XRD) Analysis

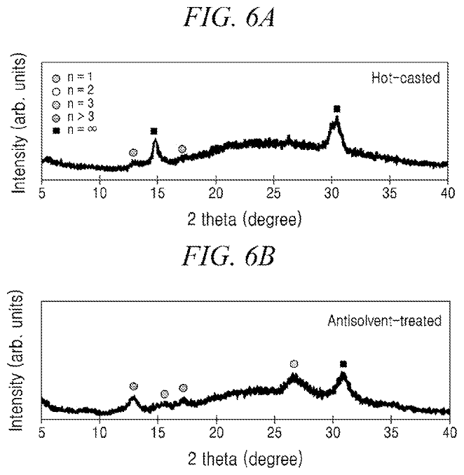

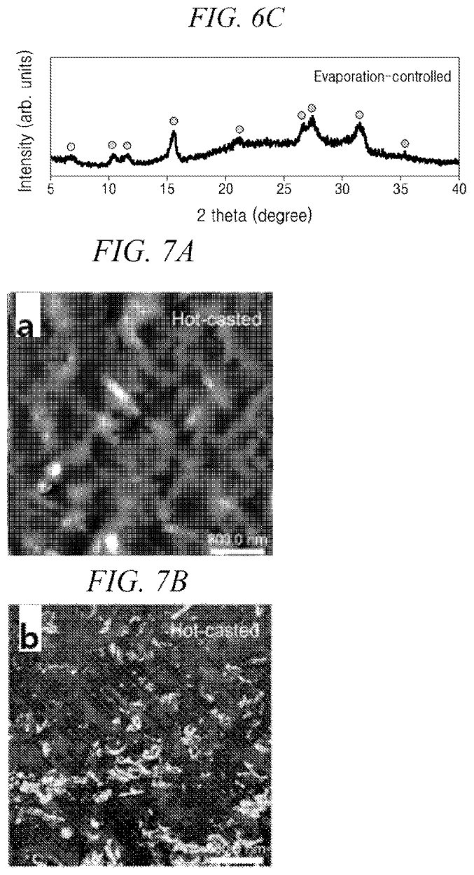

XRD of perovskite (PEA₂CsPb₂Br) thin films fabricated in Example 1 (anti-solvent evaporation-controlled method), Comparative Example 1 (hot-casting method) and Comparative Example 2 (anti-solvent method) were measured (FIGS. 6A to 6C). It was confirmed that all of the perovskite synthesized by the hot-casting method and the anti-solvent method exhibited a diffraction peak corresponding to quasi-three dimensional (n>3) perovskite, whereas the perovskite synthesized by the anti-solvent evaporation-controlled method exhibited only a diffraction peak corresponding to quasi-two dimensional (n=1, 2, 3) perovskite.

### TEST EXAMPLE 3

### Surface Morphology Analysis

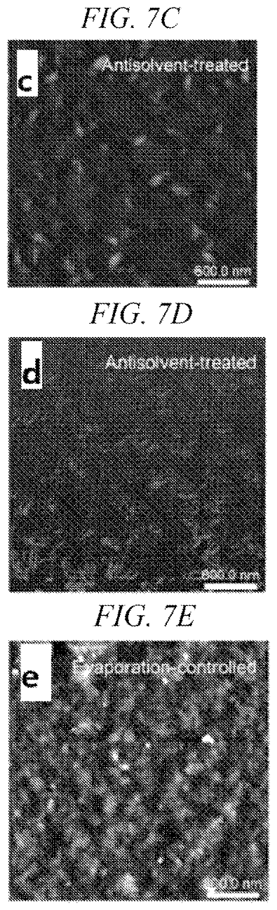

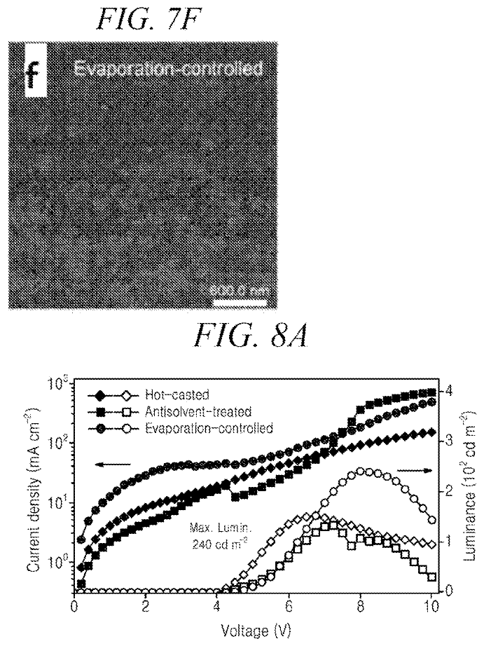

Atomic force microscopy (AFM) images of perovskite (PEA₂CsPb₂Br₇) thin films fabricated in Example 1 (anti-solvent evaporation-controlled method), Comparative Example 1 (hot-casting method) and Comparative Example 2 (anti-solvent method) were measured to obtain surface images and phase contrast images (FIGS. 7A to 7F). It was confirmed that the perovskite synthesized by the anti-solvent evaporation-controlled method had the most uniform surface morphology and the lowest phase contrast.

### TEST EXAMPLE 4

### LED Characterization

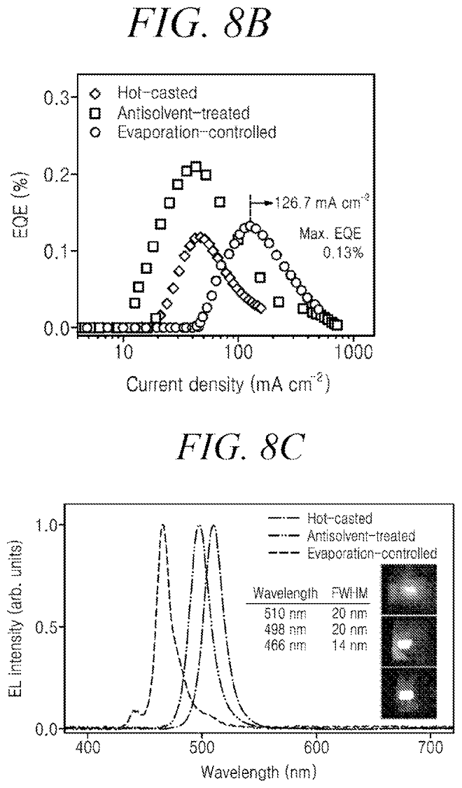

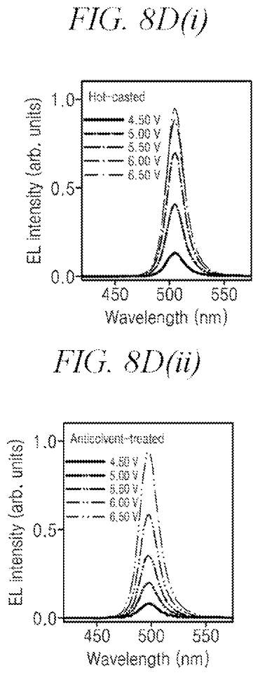

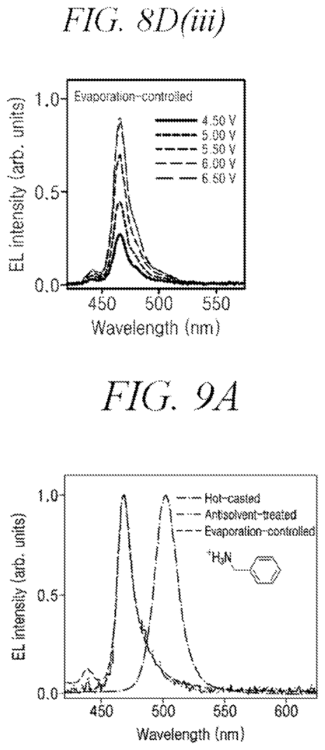

1) Characteristics of perovskite (PEA₂CsPb₂Br₇)-based LEDs fabricated in Example 1 (anti-solvent evaporation-controlled method), Comparative Example 1 (hot-casting method) and Comparative Example 2 (anti-solvent method) were analyzed (FIGS. 8A to 8C and FIGS. 8D(i) to 8D(iii)). FIG. 8A shows a current density (left) and luminance (right) graph of the LEDs and FIG. 8B shows an external quantum efficiency graph depending on the current density of the LEDs. A roll-off of external quantum efficiency of the LED based on perovskite synthesized by the anti-solvent evaporation-controlled method was observed at a current density of about 126.7 mA/cm², and the LED based on perovskite synthesized by the anti-solvent evaporation-controlled method exhibited the most stable emission characteristics. FIG. 8C and FIGS. 8D(i) to 8D(iii) show electroluminescence spectra of the LEDs, and it was confirmed that quasi-two dimensional perovskite synthesized by the anti-solvent evaporation-controlled method exhibited the narrowest phase distribution and thus emitted blue light (peak at 466 nm, FWHM 14 nm), and the spectral stability was manifested by the appearance of a peak of the electroluminescence spectrum in a predetermined wavelength band regardless of voltage and current density values.

The following Table 1 shows characteristics of the perovskite (PEA₂CsPb₂Br₇)-based LEDs fabricated in Example 1 (anti-solvent evaporation-controlled method), Comparative Example 1 (hot-casting method) and Comparative Example 2 (anti-solvent method).

TABLE 1

| | | | | | | | Power | Current |
|---|---|---|---|---|---|---|---|---|
| | λ_{EL} | FWHM | CIE | Voltage | Luminance | EQE | efficiency | efficiency |
| | (nm) | (nm) | (x, y) | (V) | (cd/m²) | (%) | (lm/W) | (cd/A) |
| hot-casting | 510 | 20 | (0.05, 0.63) | 6.75/6.00 | 150.0/135.2 | 0.10/0.12 | 0.11/0.15 | 0.25/0.29 |
| method | | | | | | | | |
| anti-solvent | 498 | 20 | (0.05, 0.05) | 7.25/6.50 | 132.4/103.1 | 0.12/0.21 | 0.06/0.12 | 0.13/0.24 |
| method | | | | | | | | |
| anti-solvent | 466 | 14 | (0.15, 0.10) | 8.00/7.25 | 240.0/200.3 | 0.11/0.13 | 0.05/0.07 | 0.13/0.16 |
| evaporation- | | | | | | | | |
| controlled | | | | | | | | |
| method | | | | | | | | |

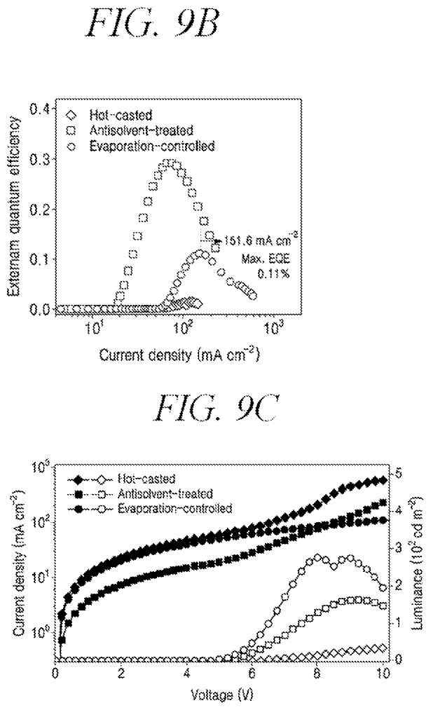

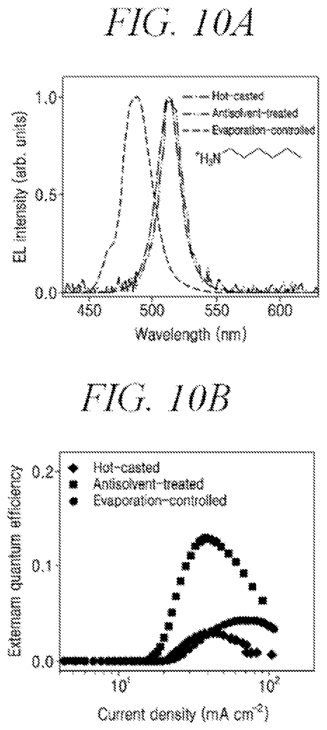

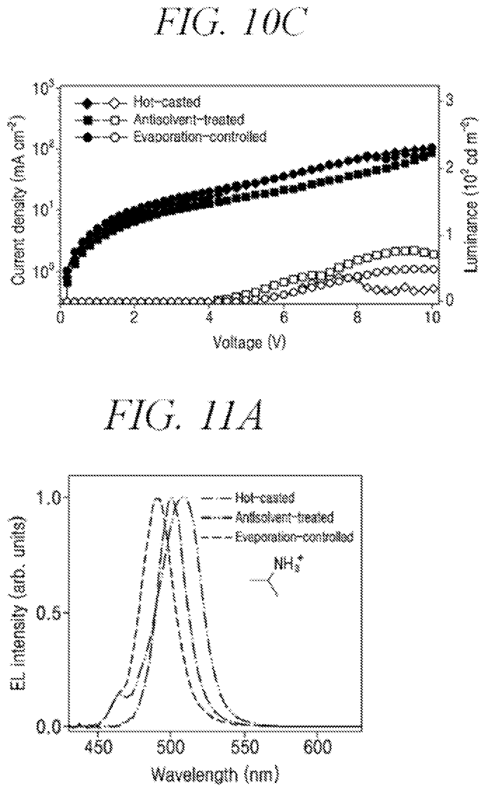

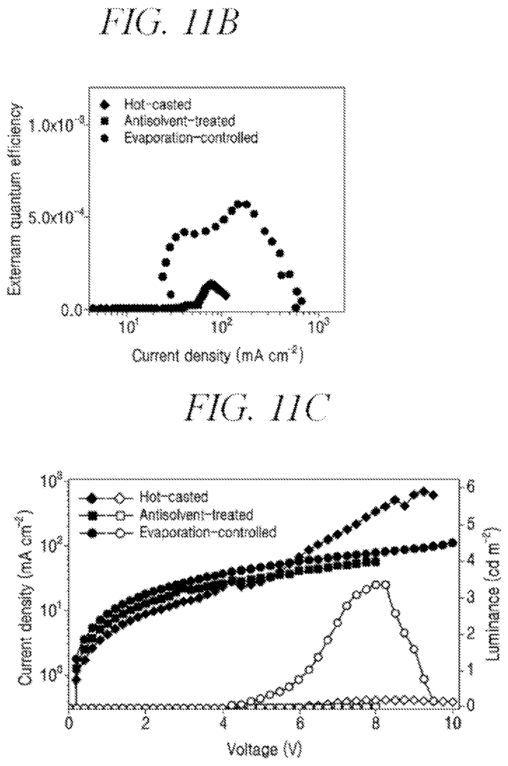

2) Characteristics of perovskite (BA₂CsPb₂Br₇, nHA₂CsPb₂Br₇, and iPA₂CsPb₂Br₇)-based LEDs fabricated in Example 2 (anti-solvent evaporation-controlled method), Comparative Example 1 (hot-casting method) and Comparative Example 2 (anti-solvent method) were analyzed (FIGS. 9A to 9C, FIGS. 10A to 10C, and FIGS. 11A to 11C). It was confirmed that all of the perovskite thin films BA₂CsPb₂Br₇, nHA₂CsPb₂Br₇, and iPA₂CsPb₂Br₇ exhibited the narrowest phase distribution when synthesized using the anti-solvent evaporation-controlled method. Accordingly, it was confirmed that the LED based on the perovskite synthesized by the anti-solvent evaporation-controlled method exhibited stable emission characteristics regardless of the kind of perovskite material.

The above description of the example embodiments is provided for the purpose of illustration, and it would be understood by those skilled in the art that various changes and modifications may be made without changing technical conception and essential features of the example embodiments. Thus, it is clear that the above-described example embodiments are illustrative in all aspects and do not limit the present disclosure. For example, each component described to be distributed can be implemented in a combined manner.

The scope of the inventive concept is defined by the following claims and their equivalents rather than by the detailed description of the example embodiments. It shall be understood that all modifications and embodiments conceived from the meaning and scope of the claims and their equivalents are included in the scope of the inventive concept.

1. A method of preparing perovskite using an anti-solvent evaporation-controlled method, comprising:
a precursor solution applying process of applying a perovskite precursor solution onto a substrate; and
an anti-solvent applying process of applying an anti-solvent onto the applied perovskite precursor solution,
wherein, in the precursor solution applying process, temperatures of the substrate and the perovskite precursor solution are in the range of ±20° C. of a boiling point of the anti-solvent.

2. The method of claim 1,
wherein the anti-solvent includes at least one selected from toluene, chlorobenzene and chloroform.

3. The method of claim 1,
wherein an evaporation rate of the anti-solvent on the applied perovskite precursor solution is uniformly controlled by setting the temperatures of the substrate and the perovskite precursor solution to the range of ±20° C. of the boiling point of the antisolvent.

4. The method of claim 1,
wherein the precursor solution applying process is performed by at least one selected from a spin-coating method, a spray-coating method, and a dip-coating method.

5. The method of claim 1, further comprising:
an annealing process after the anti-solvent applying process.

6. The method of claim 1,
wherein quasi-two dimensional perovskite crystals in which the number of unit cell (n) is an integer of 1 to 3 are obtained with a ratio of about 95% or more of all crystals by the method of preparing perovskite.

7. A perovskite prepared by the method according to claim 1, the perovskite is represented by the following Chemical Formula 1:
(ANH₃)₂B₍ₘ₋₁₎CₘX₃ₘ₊₁ [Chemical Formula 1]
wherein, in the Chemical Formula 1,
A includes an arylalkyl group or a linear alkyl group having 1 to 10 carbon atoms,
B includes at least one selected from RNH₃ and Cs,
R includes a linear or branched alkyl group having 1 to 10 carbon atoms,
C includes at least one metal cation selected from Pb²⁺, Cu²⁺, Ni²⁺, Co²⁺, Fe²⁺, Mn²⁺, Cr²⁺, Pd²⁺, Cd²⁺, Yb²⁺, Sn²⁺ and Ge²⁺,
X includes at least one halide anion selected from Cl⁻, Br⁻ and I⁻, and
m is an integer of 2 or more.

8. The perovskite of claim 7,
wherein the perovskite has a quasi-two dimensional profile in which the number of unit cell (n) is an integer of 1 to 3.

9. The perovskite of claim 7,
wherein the perovskite has a maximum photoluminescence peak at a wavelength range of 440 nm to 500 nm.

10. The perovskite of claim 7,
wherein the perovskite has a full width at half maximum of a maximum photoluminescence peak of 20 nm or less.

11. A light emitting diode, comprising the perovskite according to claim 7 as an emission layer.

12. The light emitting diode of claim 11,
wherein the light emitting diode includes a substrate, a first electrode layer formed on the substrate, a hole injection layer formed on the first electrode layer, an emission layer including the perovskite and formed on the hole injection layer, an electron transport layer formed on the emission layer, and a second electrode layer formed on the electron transport layer.

13. The method of claim 1,
wherein the anti-solvent is toluene, and
wherein the temperature of the substrate and the temperature of perovskite precursor solution are 100° C. to 120° C. respectively.

14. The method of claim 1,
wherein the precursor solution applying process and the anti-solvent applying process are performed by the spin-coating method, and
wherein the anti-solvent applying process is performed after the precursor solution applying process and before the spin-coating is completed.

15. The method of claim 1,
wherein the perovskite is represented by the following Chemical Formula 1 or 2:
(ANH₃)₂B₍ₘ₋₁₎CₘX₃ₘ₊₁ [Chemical Formula 1]
(ANH₃)₂B₍ₘ₋₁₎PbₘX₃ₘ₊₁ [Chemical Formula 2]
wherein, in the Chemical Formula 1 and Chemical Formula 2,
A includes an arylalkyl group or a linear alkyl group having 1 to 10 carbon atoms,
B includes at least one selected from RNH₃ and Cs,
R includes a linear or branched alkyl group having 1 to 10 carbon atoms,
C includes at least one metal cation selected from Pb²⁺, Cu²⁺, Ni²⁺, Co²⁺, Fe²⁺, Mn²⁺, Cr²⁺, Pd²⁺, Cd²⁺, Yb²⁺, Sn²⁺ and Ge²⁺,
X includes at least one halide anion selected from Cl⁻, Br⁻ and I⁻, and
m is an integer of 2 or more.

16. The method of claim 3,
wherein the evaporation rate of the anti-solvent on the applied perovskite precursor solution is uniformly controlled, and thus, a crystallization rate on a surface of the applied perovskite precursor solution matches a crystallization rate on the interface between the applied perovskite and the substrate.
